(19) United States
(12) Patent Application Publication
(10) Pub. No.: US 2012/0289004 A1
(43) Pub. Date: Nov. 15, 2012

(54) FABRICATION METHOD OF GERMANIUM-BASED N-TYPE SCHOTTKY FIELD EFFECT TRANSISTOR

(75) Inventors: Ru Huang, Beijing (CN); Zhiqiang Li, Beijing (CN); Yue Guo, Beijing (CN); Xia An, Beijing (CN); Quanxin Yun, Beijing (CN); Yinglong Huang, Beijing (CN); Xing Zhang, Beijing (CN)

(73) Assignee: PEKING UNIVERSITY, Beijing (CN)

(21) Appl. No.: 13/390,755

(22) PCT Filed: Oct. 14, 2011
(86) PCT No.: PCT/CN2011/080777

§ 371 Date: Feb. 16, 2012

(30) Foreign Application Priority Data
Jan. 25, 2011 (CN) 201110026949.5

(51) Int. Cl. H01L 21/336

(52) U.S. Cl. 438/151; 438/294; 257/E21.409

(57) ABSTRACT

The present invention discloses a fabrication method of a Ge-based N-type Schottky field effect transistor and relates to a filed of ultra-large-scaled integrated circuit fabrication process. The present invention forms a thin high K dielectric layer between a substrate and a metal source/drain. The thin layer on one hand may block the electron wave function of metal from inducing an MIGS interface state in the semiconductor forbidden band, on the other hand may passivate the dangling bonds at the interface of Ge. Meanwhile, since the insulating dielectric layer has a very thin thickness, and electrons can substantially pass freely, the parasitic resistances of the source and the drain are not significantly increased. The method can weaken the Fermi level pinning effect, cause the Fermi energy level close to the position of the conduction band of Ge and lower the electron barrier, thereby increasing the current switching ratio of the Ge-based Schottky transistor and improve the performance of the NMOS device.

The present application claims priority to a Chinese Patent Application (No. 201110026949.5), filed on Jan. 25, 2011 in the State Intellectual Property Office of People's Republic of China, which is incorporated herein by reference in its entirety.

### FIELD OF THE INVENTION

The invention relates to ultra-large-scale integrated (ULSI) circuit fabrication process technologies, and particularly relates to a fabrication method of a germanium-based N-type Schottky field effect (NMOS) transistor.

### BACKGROUND OF THE INVENTION

With the shrink of the feature size of CMOS devices, the development of conventional silicon-based MOS devices has reached both limits in physics and technology. Meanwhile, the deterioration of carrier mobility has become a critical factor affecting the further improvement of the device performance. In order to increase the device driving ability, using the material with high mobility for the channel is a highly effective solution. Under low electrical field, germanium material has a four times hole mobility and two times electron mobility than those of silicon material. Thus, as a new channel material, germanium material has become one of the promising solutions for high performance MOSFET devices by virtue of the higher and more symmetric carrier mobility.

As compared with silicon material, impurities in germanium material diffuse more rapidly and have lower activation ratio, and thus the doping concentrations of source and drain regions are low and it is not easy to form shallow junctions, thus resulting in an increase of the series resistance at the source and drain of a germanium-based MOS device and a deterioration of the device performance. The transistor with Schottky source and drain can effectively obviate the above problems, and hence has become a very promising device structure. The transistor having the Schottky source and drain and a conventional transistor differ in that, the former uses a metal or metal germanide source and drain instead of a conventional highly-doped source and drain, and the contact between the source/drain and a channel becomes a Schottky junction between metal and semiconductor instead of a PN junction. The transistor structure having a Schottky source and drain not only prevents the problems of low solid solubility and rapid diffusion of impurities, but also ensures low resistivity and obtains an abrupt source and drain junction.

The Ge-based Schottky transistor has the following advantages. (1) The source and the drain are formed of metal or metal germanide, so that the parasitic resistance of the source and the drain is significantly reduced. (2) The fabrication process of the Schottky transistor is completely compatible with the conventional CMOS process, and the fabrication procedure is simple. (3) The Schottky contact without an injection of minority carriers does not have a parasitic transistor effect, thus eliminating a latch-up effect bothering the CMOS circuit. (4) The thermal budget of the process is low, which benefits the process integration of high k dielectric, metal gate, strained channel, etc. (5) The germanium material has high mobility and better speed characteristic, thus the high frequency characteristic of the Ge-based device is much better than that of the conventional Si-based device.

However, the performance of the Ge-based Schottky transistor is also limited by a Schottky barrier between the source/drain and the channel. Due to the interface state at the interface between the source/drain and the substrate of the Ge-based Schottky transistor, the Fermi level is pinned in the vicinity of the valence band of Ge, which causes a high electron barrier and a low hole barrier, so that the performance improvement of the Ge-based Schottky transistor (in particular, NMOS) is limited. Firstly, the height of an electron barrier at the source terminal is an important factor to determine the magnitude of on-state current. The high electron barrier limits the injection of electrons from the source terminal, which causes a smaller on-state current. Secondly, the low hole barrier at the drain terminal causes an excessively large off-state leakage current. Moreover, the high electron barrier causes electrons from the source terminal enter into the channel mainly by way of tunneling, so that the subthreshold slope of the device become larger. In a word, the height of electron barrier becomes one of the critical factors affecting the performance of the Ge-based Schottky source/drain NMOS transistor. In order to reduce the height of electron barrier, the Fermi level pinning effect must be weakened or eliminated. The Fermi level pinning effect is caused by the following two factors. Firstly, interface states are formed by factors such as dangling bonds or defects at the surface of the Ge material. Secondly, according to the Heine theory, a metal-induced-gap-state is produced in the forbidden band of the Ge material due to incompletely attenuation of electron wave function of metal in Ge. Furthermore, problems also exist in a gate dielectric of the Ge-based MOS device, thus an interface layer usually interposed to improve the performance of gate capacitor.

### SUMMARY OF THE INVENTION

For the above problems occurred in a Ge-based Schottky source/drain NMOS transistor, the present invention can weaken the Fermi level pinning effect, lower the electron barrier, and improve the performance of the Ge-based Schottky source/drain NMOS transistor by depositing a thin high K dielectric layer in the source and the drain region of the transistor.

A method for fabricating the Ge-based Schottky source/drain NMOS transistor of the present invention is briefly described below, and the method includes the following steps:

1-1) forming a MOS transistor structure on Ge-based substrate:

1-2) depositing a high K dielectric layer on the source and drain region, and the dielectric layer has an optical frequency dielectric constant ∈_{∞}<4.5 and a conduction band offset ΔE_{c}<2 eV;

1-3) sputtering a thin metal film with low work function;

1-4) forming the source and the drain of metal; and

1-5) forming contact holes and metal connection lines.

The step 1-1) includes:

2-1) forming isolation regions on the substrate;

2-2) depositing a gate dielectric layer;

2-3) forming a gate structure; and

2-4) forming a sidewall structure.

In the step 1-1), the Ge-based substrate may be a bulk Ge substrate, a germanium-on-insulator (GOI) substrate, or an epitaxial Ge substrate.

In the step 1-2), the insulating dielectric layer may use a high K dielectric material such as yttrium oxide (Y₂O₃), hafnium oxide (HfO₂) and zirconium oxide (ZrO₂).

In the step 1-3), the metal thin film may be an aluminum film or other metal films with low work function.

The source and drain of the Schottky transistor are fabricated to have a raised structure, a recessed structure, or other novel structures such as a FinFET.

As compared with the prior art, the present invention has the following beneficial effects.

By interposing the high K dielectric layer with a thickness of 1-3 nm between the metal source/drain and Ge substrate, a Schottky barrier between the source/drain and the channel is effectively modulated, a current switching ratio of the device is increased, and the subthreshold slope of the device is reduced. The dielectric layer, on one hand, may block the electron wave function of metal to induce an MIGS interface state in the forbidden band of the semiconductor, and on the other hand, may passivate the dangling bonds at the interface of Ge. Meanwhile, since the insulating dielectric layer is very thin, electrons may substantially pass through the insulating dielectric layer freely and parasitic resistances of the source and the drain are not significantly increased. In a word, the method can weaken the Fermi level pinning effect, cause the Fermi level shift to the conduction band of Ge, lower the electron barrier, and particularly improve the performance of the NMOS device. Compared with the insulating dielectric layer using other material such as aluminum oxide (Al₂O₃), yttrium oxide (Y₂O₃) used in a preferred embodiment of the invention has an excellent interface contact with Ge, which can effectively weaken the Fermi level pinning effect and lower the Schottky electron barrier. Moreover, yttrium oxide (Y₂O₃) may also be used as a gate dielectric passivation layer. Meanwhile, the fabrication process is simple and compatible with a convention silicon CMOS process.

In order to effectively suppress the Fermi level pinning effect, the insulating dielectric layer is required to have an optical frequency dielectric constant ∈_{∞}<4.5 and a conduction band offset ΔE_{c}<2 eV. The material of the insulating layer used in the present invention is a high K dielectric material such as yttrium oxide (Y₂O₃), hafnium oxide (HfO₂) and zirconium oxide (ZrO₂). The optical frequency dielectric constants ∈_{∞} of these materials are all substantially less than 4, thereby the pinning coefficient S are all greater than 0.5. Moreover, according to experimental result, the conduction band offsets thereof are all about 1.5 eV which induces smaller tunneling resistance. Therefore, these materials can all effectively weaken the Fermi level pinning effect, and modulate the Schottky barrier between source/drain and the channel.

### BRIEF DESCRIPTION OF THE DRAWINGS

FIG. 1 shows flow diagrams for fabricating a Ge-based Schottky source/drain NMOS transistor according to the present invention.

### DETAILED DESCRIPTION OF THE EMBODIMENTS

Hereafter, the present invention will be further described in more detail with reference to the attached drawings and specific embodiments.

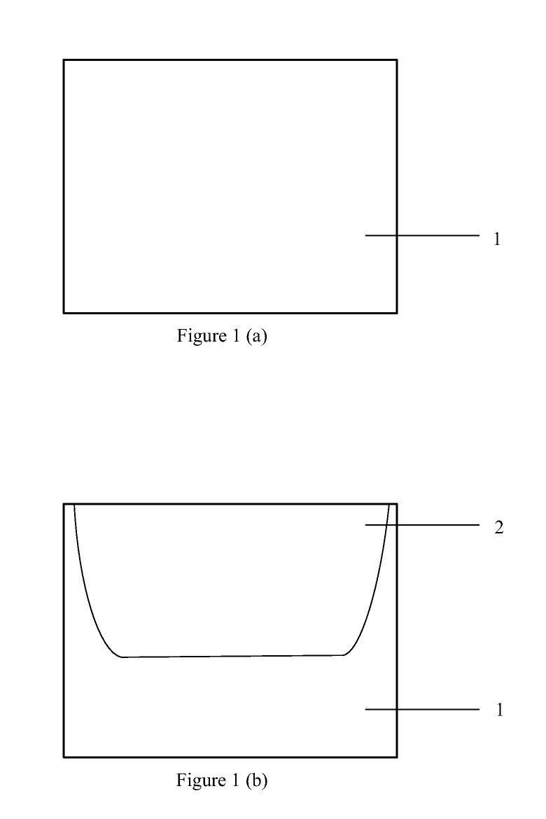

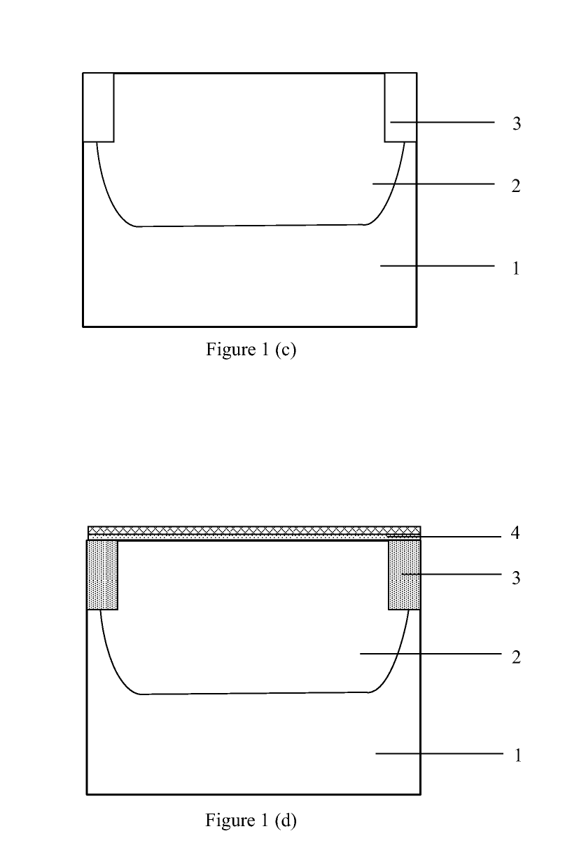

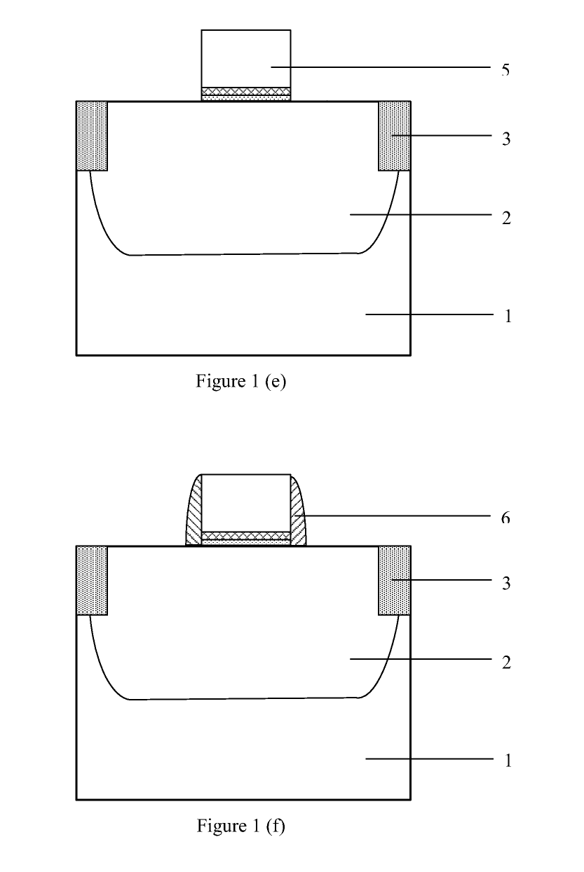

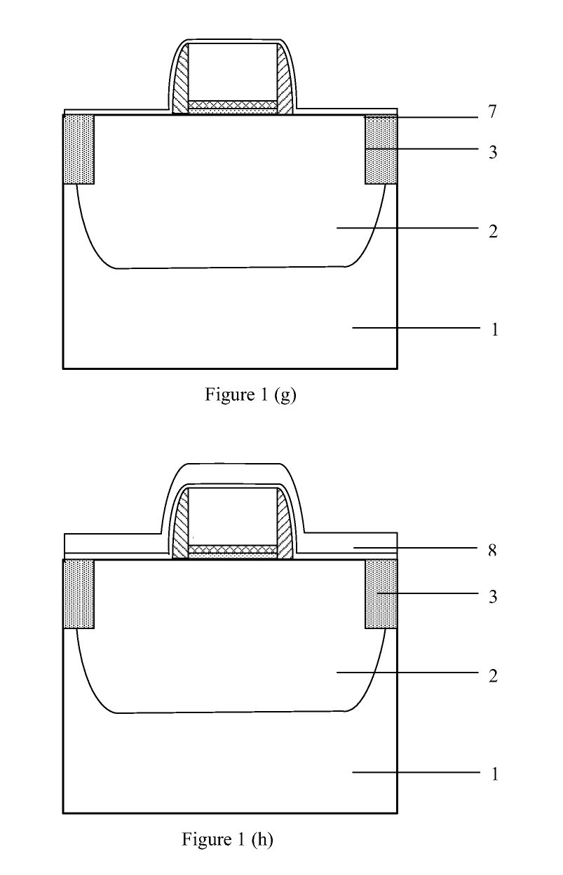

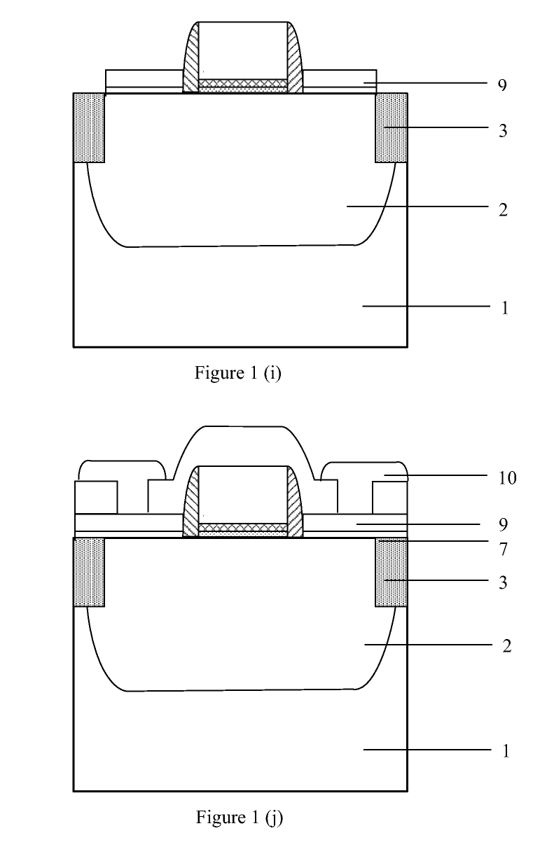

With reference to FIG. 1, a preferred embodiment of the present invention provides a fabrication method of a Ge-based Schottky source/drain NMOS transistor. The method includes the following steps.

Step 1: providing a Ge-based substrate. As shown in FIG. 1(a), a P type semiconductor Ge substrate 1 is provided, wherein, the semiconductor Ge substrate 1 may be a bulk Ge substrate, a germanium-on-insulator (GOI) substrate, or an epitaxial Ge substrate and so on.

Step 2: forming an N well region. A silicon oxide layer is deposited on the Ge substrate and then a silicon nitride layer is deposited. An N well region is defined by photolithography. A reactive on etching is performed on the silicon nitride layer in the N well region, and then N type impurities, such as P (phosphorus), are implanted by ion implanting. Subsequently, an annealing is performed to form the N well 2. Finally the mask layer used in the implantation is removed to form a structure as shown in FIG. 1(b).

Step 3: forming a trench isolation. As shown in FIG. 1(c), in isolation regions 3, a silicon oxide layer and a silicon nitride layer are deposited over the Ge substrate sequentially. Positions of trenches are defined by photolithography, and then the silicon nitride layer and the silicon oxide layer are etched by a reactive on etch technology, and thus the Ge substrate is etched to form trenches. Silicon oxide is deposited to fill the trenches by using a CVD method. A surface of the resultant structure is polished through a chemical mechanical polishing technology, so that an isolation between devices is finally implemented. The isolation for devices is not limited to a shallow trench isolation, and a field oxide isolation technology and the like may be used also.

Step 4: forming a gate dielectric layer on the active region. The dielectric layer may be formed of high K dielectric material, germanium oxide, germanium oxynitride or the like. Before depositing the gate dielectric layer, it is necessary to perform a surface passivation using PH₃ and NH₃, or to deposit an interface layer, such as silicon (Si), aluminum nitride (AlN) and yttrium oxide (Y₂O₃). In a preferred embodiment, a thin yttrium oxide (Y₂O₃) layer is firstly formed over the Ge substrate as the interface layer, and then a hafnium oxide (HfO₂) dielectric layer 4 is deposited by using an ALD deposition method, as shown in FIG. 1(d).

Step 5: forming a gate on the gate dielectric layer. The gate may be a polysilicon gate, a metal gate or a FUSI gate etc. In the embodiment, metallic titanium nitride (TiN) is deposited to form the gate. Then a gate structure is defined by photolithography and the redundant parts are removed by etching, as a metal gate 5 shown in FIG. 1 (e).

Step 6: forming sidewalls at both sides of the gate. Sidewalls may be formed by depositing and etching a SiO₂ or Si₃N₄ layer. A dual sidewall at each side may be formed by sequentially depositing Si₃N₄ layer and SiO₂ layer. As shown in FIG. 1(f), in the embodiment, an isolation structure 6 (a sidewall structure) located at both sides of the gate may be formed by depositing and dry etching a silicon oxide layer.

Step 7: depositing a high K dielectric layer in source and drain regions. The high K dielectric layer is formed by depositing and oxidizing a thin metal layer or by a direct deposition through ALD equipment. Since the thin layer is used to adjust the barrier between source/drain and channel, it is required for the dielectric layer that an optical frequency dielectric constant ∈_{∞}<4.5 and a conduction band offset ΔE_{c}<2 eV. High K dielectric materials such as yttrium oxide (Y₂O₃), hafnium oxide (HfO₂), zirconium oxide (ZrO₂) and the like meet the above requirements. In the preferred embodiment, yttrium oxide (Y₂O₃) which has a thickness of 1-3 nm is used, as the thin layer 7 shown in FIG. 1(g).

Step 8: sputtering a metal film with low work function. Metals such as aluminum (Al), titanium (Ti) and yttrium (Y) may be used. In the preferred embodiment, aluminum (Al) is used. An aluminum film 8 with a thickness in a range of 50-500 nm may be deposited over the semiconductor substrate by using a physical vapor deposition, such as vaporization or sputtering, as shown in FIG. 1(h).

Step 9: forming a metal source and drain. As shown in FIG. 1(i), a pattern is defined by photolithography and then an etching process is performed to form source and drain structures, so that the metal source and drain 9 are obtained.

Step 10: forming contact holes and metal connection lines. An oxide layer is deposited by a chemical vapor deposition method. Positions of contact holes are defined by photolithography and the silicon oxide layer is etched to form the contact holes. Then, a metal layer, such as Al and Al—Ti is sputtered. Patterns of connection lines are defined by photolithography, and metal connection line patterns are formed after etching the metal layer. Finally, a metal connection line layer 10 is formed by alloying through a low temperature annealing, so that the structure as shown in FIG. 1(j) is formed.

The present invention proposes a fabrication method of a Ge-based NMOS Schottky transistor. The method not only lowers the barrier height of electrons at the source and the drain of the NMOS transistor, improves the current switching ratio of the Ge-based Schottky NMOS transistor, improves the performance of the Ge-based Schottky NMOS transistor, but also is compatible with a silicon CMOS technology, thus has an advantage of simple process. As compared with the conventional process fabrication method, the semiconductor device structure and the fabrication method thereof according to the invention may easily and effectively improve the performance of the Ge-based Schottky NMOS transistor.

The fabrication method according to the present invention has been described in detail above by the preferred embodiment. Those skill in the art should understand that, the above-mentioned is only a preferred embodiment of the present invention, and the device structure of the present invention may be changed or modified without departing from the substantial scope of the present invention. For example, a raised or a recessed source and drain structure, or other structures such as a FinFET (Fin-shaped Field-Effect-Transistor) etc. may be used. Meanwhile, the fabrication method of the device structure of the present invention is not limited to the content disclosed in the embodiment. All equivalent changes and modifications made according to the claims of the present invention are all within the scope of the present invention.

What is claimed is:

1. A fabrication method of a Ge-based N-type Schottky field effect transistor, comprising the following steps:
1-1) forming a MOS transistor structure on a Ge-based substrate;
1-2) depositing a high K dielectric layer on a source and a drain region, and the dielectric layer has an optical frequency dielectric constant ∈_{∞}<4.5 and a conduction band offset ΔE_{c}<2 eV;
1-3) sputtering a thin metal film with low work function;
1-4) forming the source and the drain region of metal; and
1-5) forming contact holes and metal connection lines.

2. The fabrication method according to claim 1, characterized in that, the step 1-1) comprises:
2-1) forming isolation regions on the substrate;
2-2) depositing a gate dielectric layer;
2-3) forming a gate structure; and
2-4) forming a sidewall structure.

3. The fabrication method according to claim 1, characterized in that, the Ge-based substrate is a bulk Ge substrate, a germanium-on-insulator (GOI) substrate, or an epitaxial Ge substrate.

4. The fabrication method according to claim 1, characterized in that, the source and the drain of the Schottky transistor are fabricated to have a rasied structure, a recessed structure, or a Fin FET structure.

5. The fabrication method according to claim 1, characterized in that, the high K dielectric layer is made of yttrium oxide (Y₂O₃), hafnium oxide (HfO₂), or zirconium oxide (ZrO₂).

6. The fabrication method according to claim 1, characterized in that, the high K dielectric layer has a thickness of 1-3 nm.

7. The fabrication method according to claim 1, characterized in that, in the step 1-3), the metal thin film is an aluminum film or other metal films of a low work function.
